(19) United States
(12) Patent Application Publication
(10) Pub. No.: US 2003/0012925 A1
(43) Pub. Date: Jan. 16, 2003

(54) Process for fabricating semiconductor structures and devices utilizing the formation of a compliant substrate for materials used to form the same and including an etch stop layer used for back side processing

(75) Inventor: Jonathan F. Gorrell, Pompano Beach, FL (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/905,110

(22) Filed: Jul. 16, 2001

(51) Int. Cl. H01L 31/112; B32B 3/10; H01L 29/76; H01L 31/036

(52) U.S. Cl. 428/137; 428/138

(57) ABSTRACT

Highly controlled, highly aligned monolithic integration of devices in a high quality monocrystalline material layer (26) with vias (211, 231) fabricated in an underlying monocrystalline substrate (22) in a single monolithic three dimensional architecture (20, 34). Excellent compliancy is achieved in a monolithic semiconductor structure (20, 34) by processes described herein while at the same time fabrication of via openings (211, 231) in the monocrystalline substrate (20, 34) can be made in a controlled, aligned manner to the back side (263) of a high quality monocrystalline film (26). Conductive connections (219, 239) can be made to devices (271, 273) in the high quality monocrystalline layer (26) from its backside (263).

### FIELD OF THE INVENTION

This invention relates generally to processes for fabricating semiconductor structures and devices and the resulting structures, and more specifically to processes for fabricating semiconductor structures and devices, and the resulting structures and their usages, including a monocrystalline compound semiconductor layer and a monocrystalline semiconductor substrate in which the semiconductor structure is processed using an etch stop layer.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals. There also is a need for such semiconductor structures which additionally permit highly controlled, highly aligned monolithic integration of devices in the high quality monocrystalline material layer with structures fabricated in the monocrystalline substrate.

Prior art etch stops include those used in thinning of entire silicon wafers of bonded pairs for device layers involving a layer transfer approach in which a predetermined thin and uniform silicon layer on a silicon device wafer is transferred onto a desired substrate, i.e., a handle wafer. This layer transfer is commonly achieved by bonding and subsequent chemical etch-back of the silicon device wafer in which a predetermined thin and uniform silicon layer is formed on top of a built-in etch stop. It is known to use implanted active impurities such as boron, boron/germanium, carbon, nitrogen, or oxygen, to form such etch stop layers. However, problems are associated with heavy doping of such impurities in silicon to provide etch stop layers, such as out-diffusion and misfit dislocations problems. Moreover, those prior etch stops were not designed for use in complex monolithic substrates such as where significant lattice constant mismatches must be addressed between different constituent layers thereof formed of different single crystal semiconductor materials.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIGS. 24, 25 illustrate schematically, in cross section, device structures that can be used in accordance with various embodiments of the invention;

FIGS. 26-30 include illustrations of cross-sectional views of a portion of an integrated circuit that includes a compound semiconductor portion, a bipolar portion, and an MOS portion in accordance with what is shown herein;

FIGS. 31-37 include illustrations of cross-sectional views of a portion of another integrated circuit that includes a semiconductor laser and a MOS transistor in accordance with what is shown herein;

FIG. 38 illustrates schematically, in cross section, a composite semiconductor structure useful for back side processing in accordance with the invention;

FIG. 39 illustrates schematically, in cross section, a process for etch processing from the back side of a composite semiconductor structure in accordance with an embodiment of the invention using the structure of FIG. 38 (FIG. 1);

FIG. 40 illustrates schematically, in cross section, a process for etch processing from the back side of a composite semiconductor structure in accordance with an alternative embodiment of the invention using the structure of FIG. 3;

FIG. 41 illustrates schematically, in cross section, an alternative process for etch processing from the back side of a composite semiconductor structure in accordance with an embodiment of the invention using the structure of FIG. 38;

FIGS. 42-44 illustrate schematically, in cross section, another alternative process for etch processing from the back side of a composite semiconductor structure and forming via connections therein in accordance with an embodiment of the invention using the structure of FIG. 38;

FIG. 45 illustrates schematically, in cross section, a process for forming a conductive via connection in a composite semiconductor structure according to FIG. 3 in accordance with an alternative to the embodiment illustrated in FIGS. 42-44;

FIG. 46 illustrates schematically, in cross section, a process for forming a thermal via connection in a composite semiconductor structure in accordance with another embodiment of the invention using the structure of FIG. 38; and

FIG. 47 illustrates schematically, in cross section, a process for forming a vertical cavity surface emitting laser in a composite semiconductor structure in accordance with another embodiment.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

The present invention generally relates to highly controlled, highly aligned monolithic integration of devices in a high quality monocrystalline material layer, such as a Group III-V semiconductor layer, with vias fabricated in an underlying monocrystalline substrate, such as a silicon substrate, in a single monolithic three dimensional architecture. As will be understood from the following description, excellent compliancy is achieved in a monolithic semiconductor structure by processes described herein while at the same time fabrication of via openings in the monocrystalline substrate can be made in a controlled, aligned manner to the back side of the high quality monocrystalline film. In this way, for example, conductive connections can be made to devices in the high quality monocrystalline layer from its backside. Among other things, this permits more effective use of the real estate on the high quality monocrystalline film. Alternatively, the via openings can be formed as thermal vias to dissipate heat from devices in the high quality monocrystalline layer. In addition, via openings can be etched through the monocrystalline substrate to the back side of optoelectronic devices in the high quality monocrystalline layer to provide an exit for light or other optical radiation generated by bottom emitting vertical cavity surface emitting lasers, light emitting diodes, or other like optoelectronic devices, fabricated in the high quality, monocrystalline layer.

In processing a composite semiconductor structure according to this invention, in general, anisotropic etching is conducted through patterned, exposed areas of the monocrystalline semiconductor substrate until exposing the etch stop layer comprising a metal oxide, where the metal comprises at least two different metallic elements, such as a perovskite oxide material. In one embodiment, an anisotropic wet etch is performed for this process stage that is an orientation-dependent crystallographic etch of the semiconductor substrate, and which stops at the metal oxide etch stop layer. In an alternative embodiment, a dry etch process is performed on the semiconductor substrate that is susceptible to end point detection via spectroscopic method upon reaching the metal oxide etch stop film. As yet another embodiment, a combination of these wet and dry etch procedures can be used to start and complete, respectively, the etch of a via, in order to take advantage of a relatively higher speed wet etch for bulk removal and the accommodation of high precision end point detection techniques possible with dry etching.

Due to thickness variations that occur and still remain in sliced and lapped semiconductor wafers, wet or dry etching through the thickness of the semiconductor substrate usually will require over etch, such as approximately 150% over etch for silicon wafers, to avoid under etches. The perovskite oxide buffer layer protects the monocrystalline material layer from uncontrolled etchant attack during formation of the vias in the semiconductor substrate, especially during such over etch conditions. In this way, the perovskite oxide buffer layer also serves as an etch stop layer.

In a further embodiment of the invention, the exposed portions of the etch stop regions located at the bottom of the vias formed in the etched monocrystalline substrate are subjected to etching so that the via opening or hole is advanced (extended) through the etch stop layer until exposing backside portions of the high quality monocrystalline material layer. The process in accordance with this invention ensures that the vias reaching the back side of the high quality monocrystalline material layer are in good alignment with the original openings started on the monocrystalline substrate.

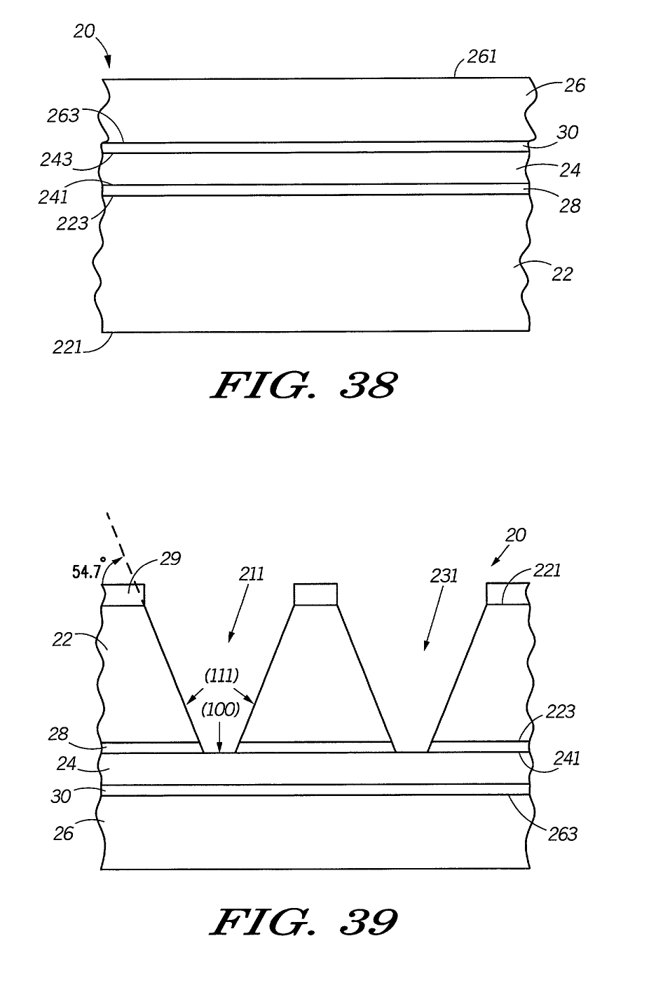

An advantage of this invention resides in that the perovskite oxide buffer/etch stop layer is multi-tasked in the composite semiconductor structure processed according to the invention. Namely, in one role, it forms a permanent accommodating buffer layer in the lattice-mismatched composite structure such that the high quality, relatively thinner layer of monocrystalline material can be formed with minimal crystal and dislocation defects otherwise caused by lattice mismatch with the semiconductor substrate. In addition, and discussed above, the buffer layer separately serves an etch stop layer during fabrication of vias started in the semiconductor substrate of the composite semiconductor structure. Exemplary embodiments of this process are schematically illustrated in FIGS. 38-47, which will be discussed in greater detail below.

The fabrication of the compliant semiconductor structure used as the workpiece for the back side processing according to this invention are first discussed below in connection with FIGS. 1-23, and then the back side processing of particular interest herein is described in greater detail by way of examples and FIGS. 38-47.

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

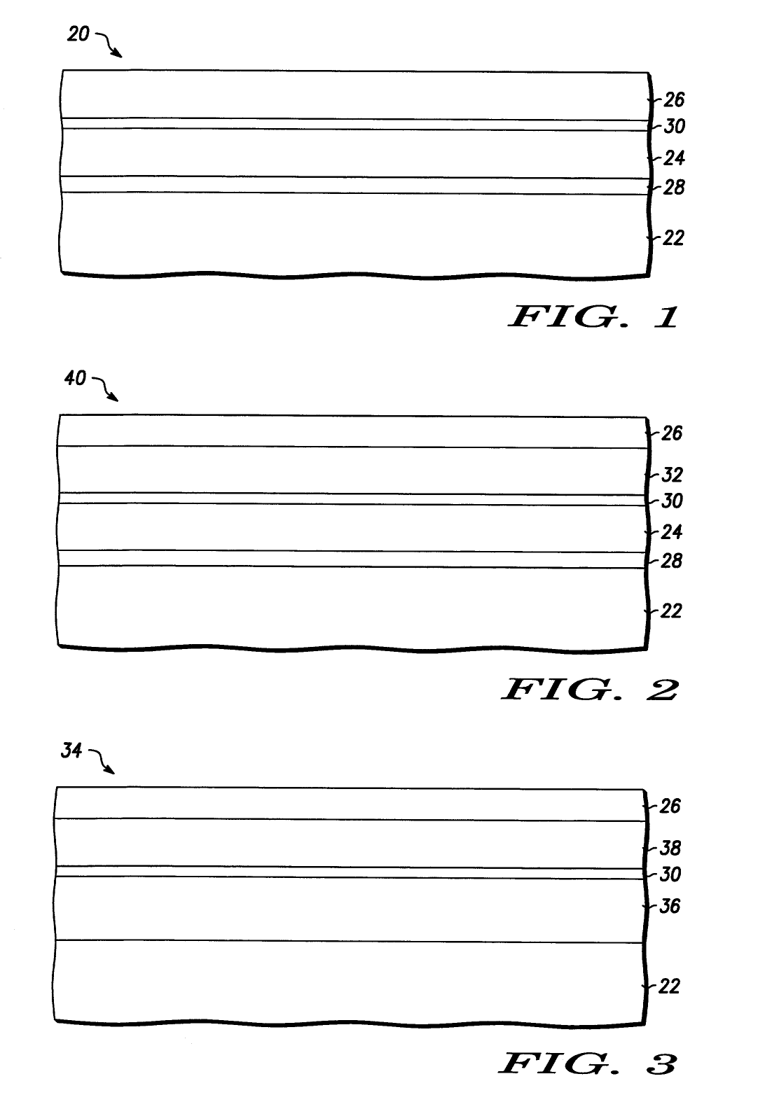

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓPₗ₋ₓ superlattice, wherein the value of x ranges from 0 to 1. In accordance with another aspect, buffer layer 32 includes an In_{y}Ga_{l-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

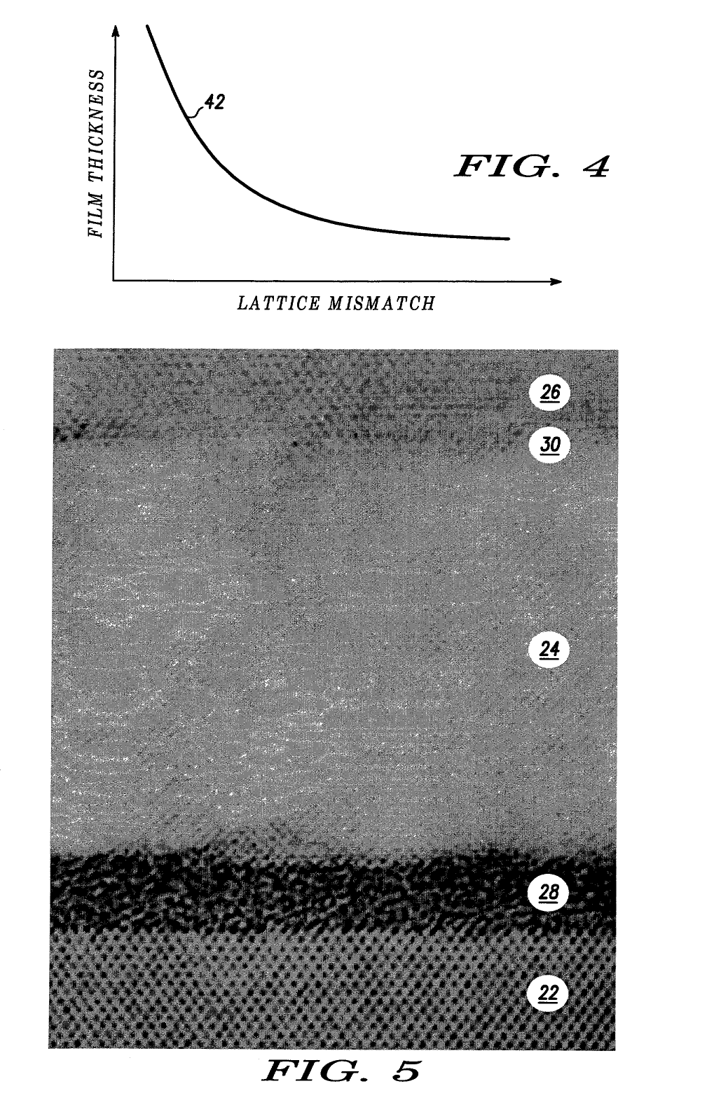

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45 degree with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa_{1-z}TiO₃, substantial matching of crystal lattice constants of the two materials is achieved, wherein the crystal orientation of the grown layer is rotated by 45 degrees with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45 degrees with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45 degrees with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

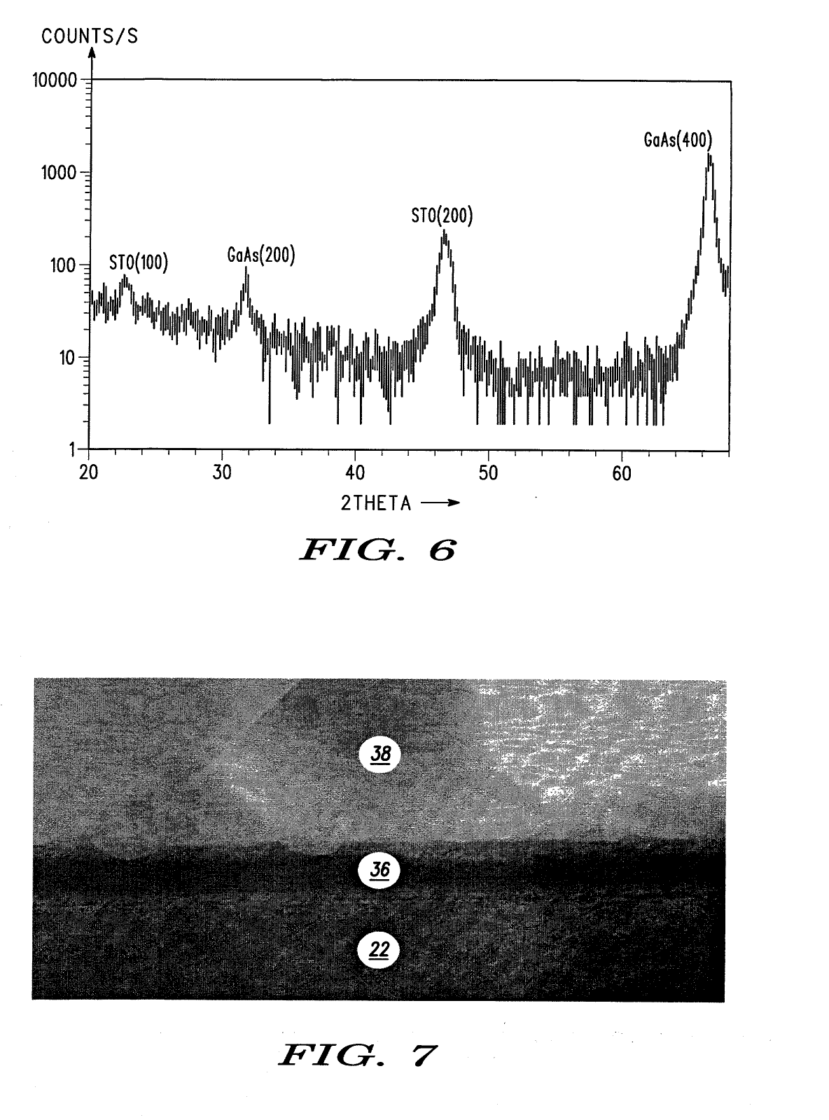

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700□ C. to about 1000□ C. and a process time of about 5 seconds to about 10 minutes. However, other suitable anneal processes may be employed to convert the accommodating buffer layer to an amorphous layer in accordance with the present invention. For example, laser annealing, electron beam annealing, or Aconventional@ thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

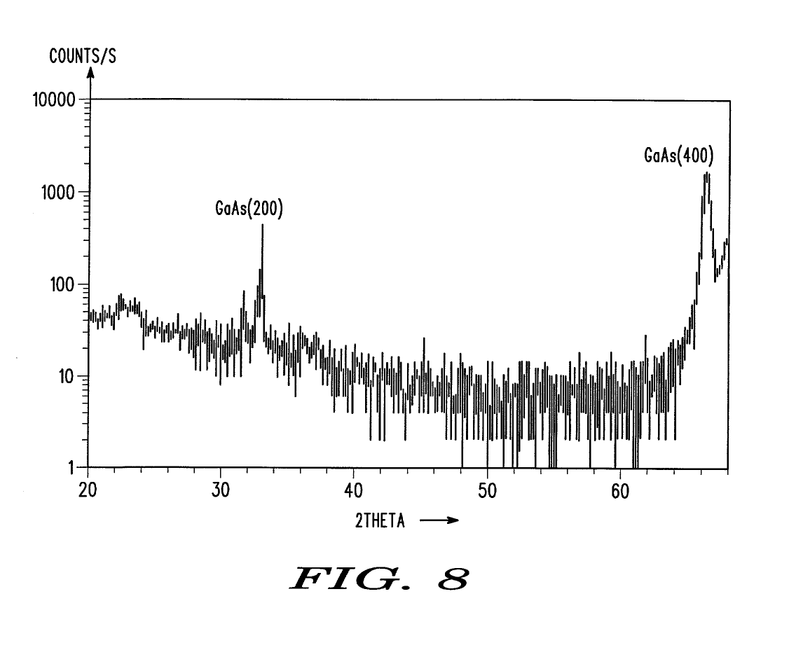

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

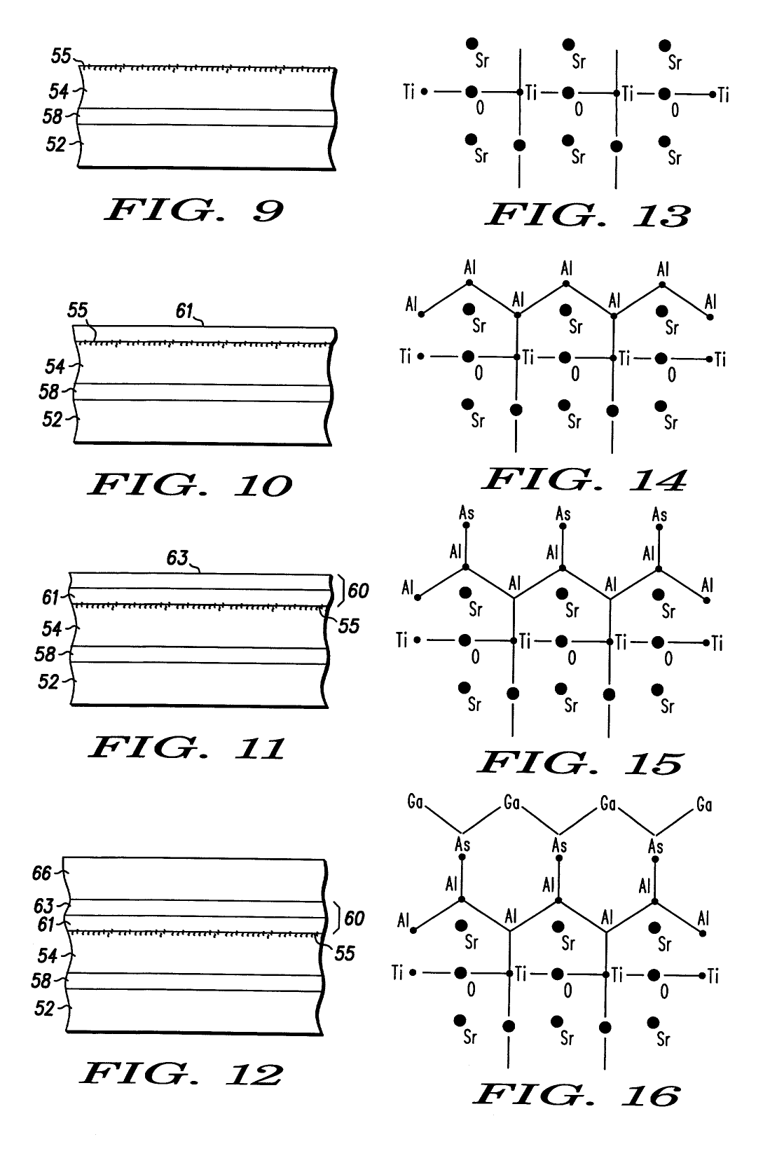

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800EC. to 1000EC. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

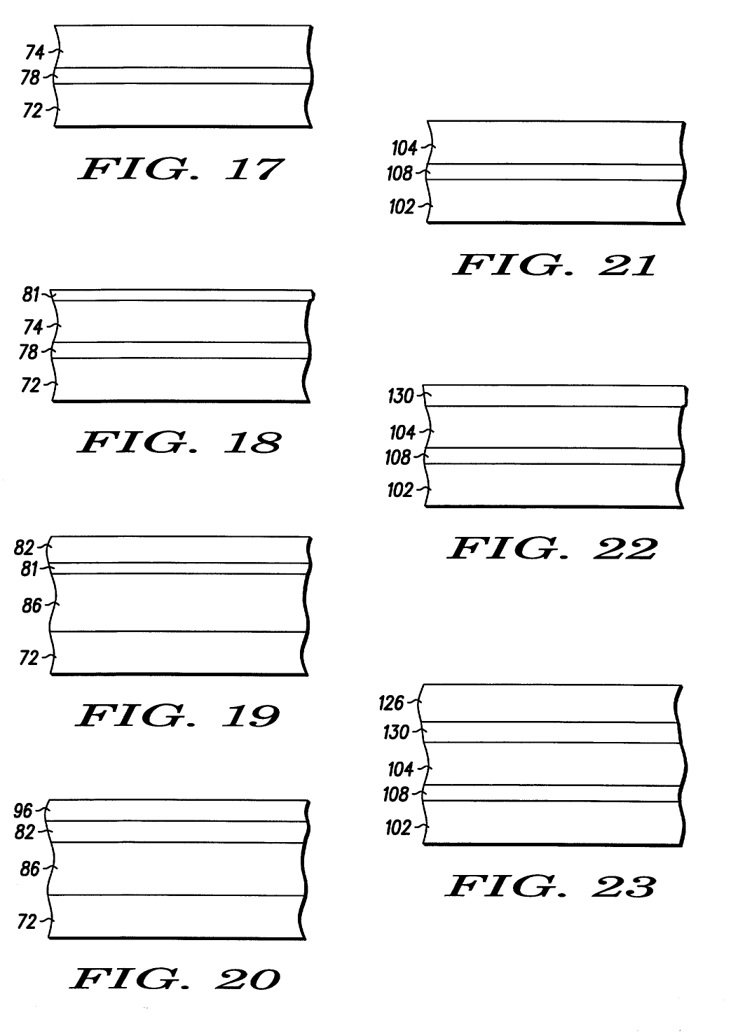

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a Asoft@ layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and processes for fabricating material layers which form semiconductor structures, devices and integrated circuits including other layers such as metal and non-metal layers. More specifically, the invention includes structures and processes for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

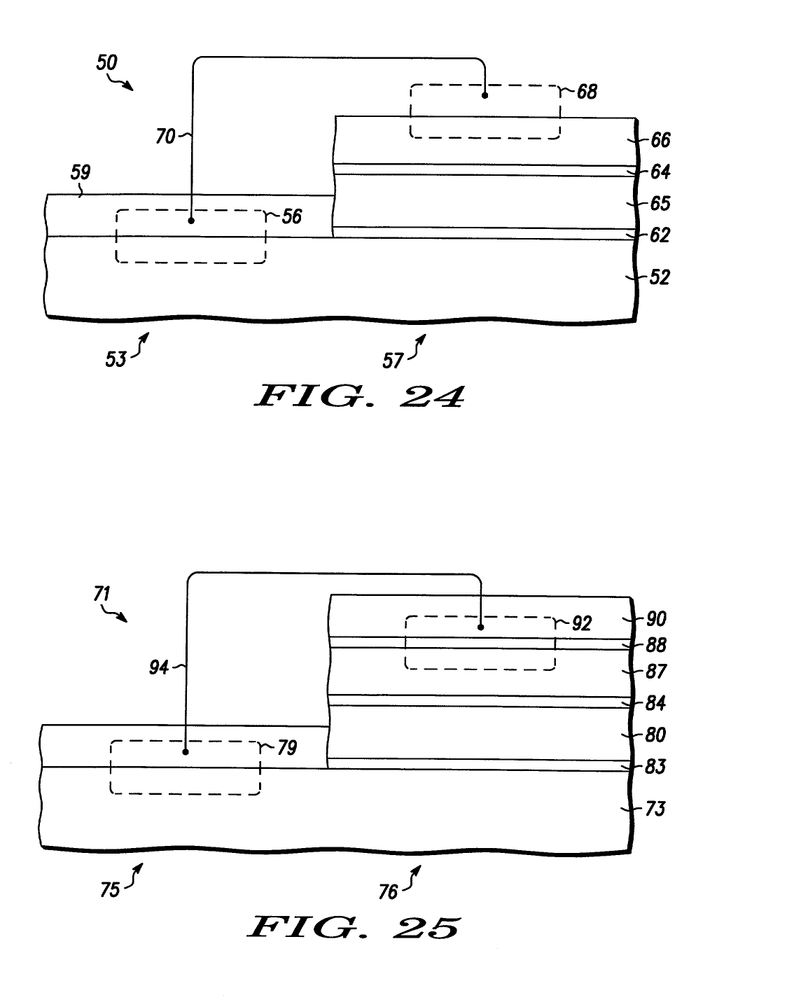

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 86 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

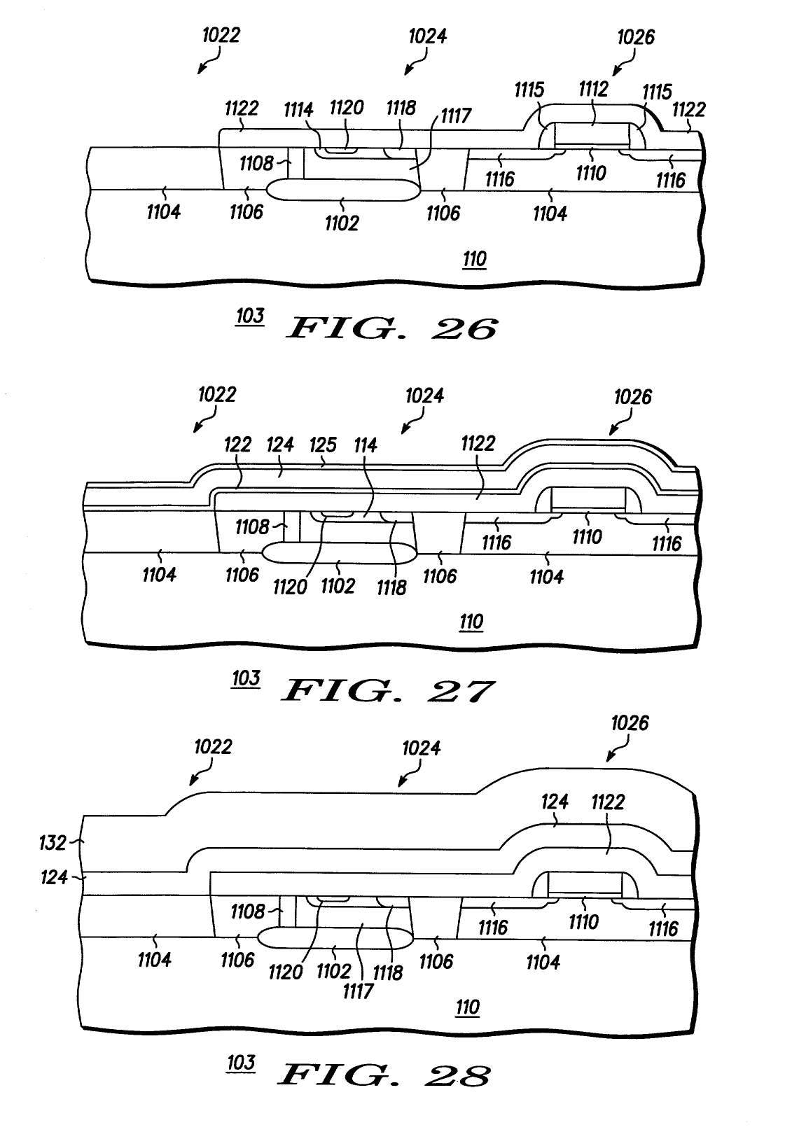

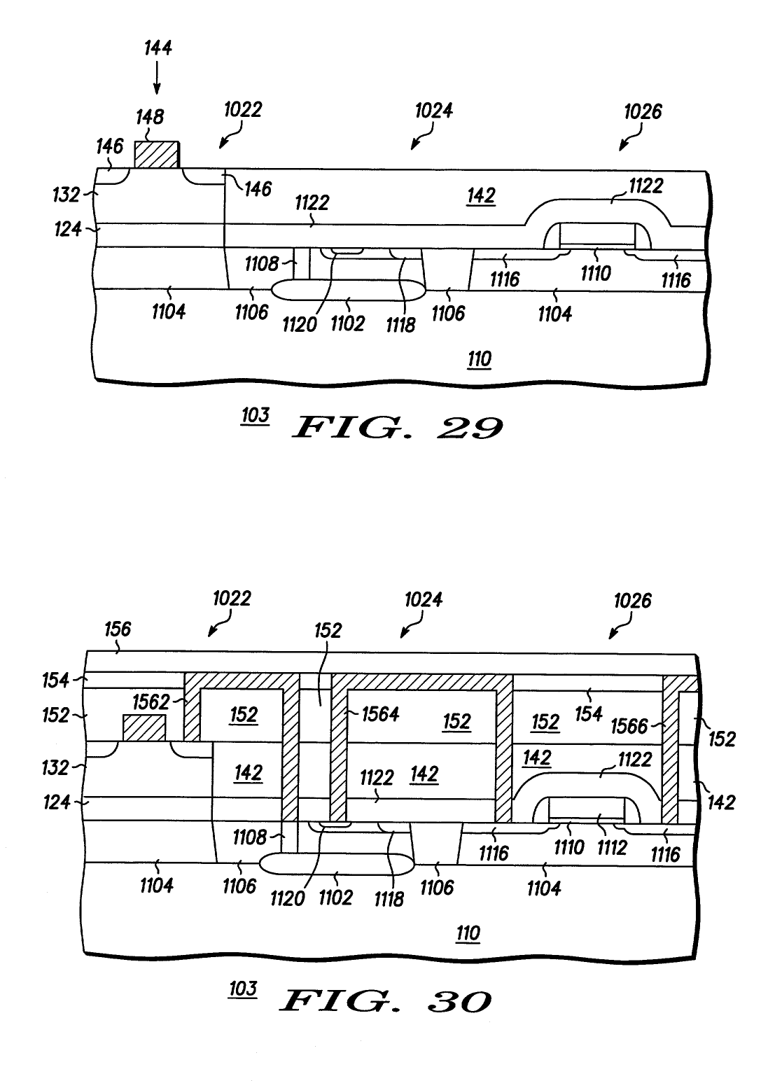

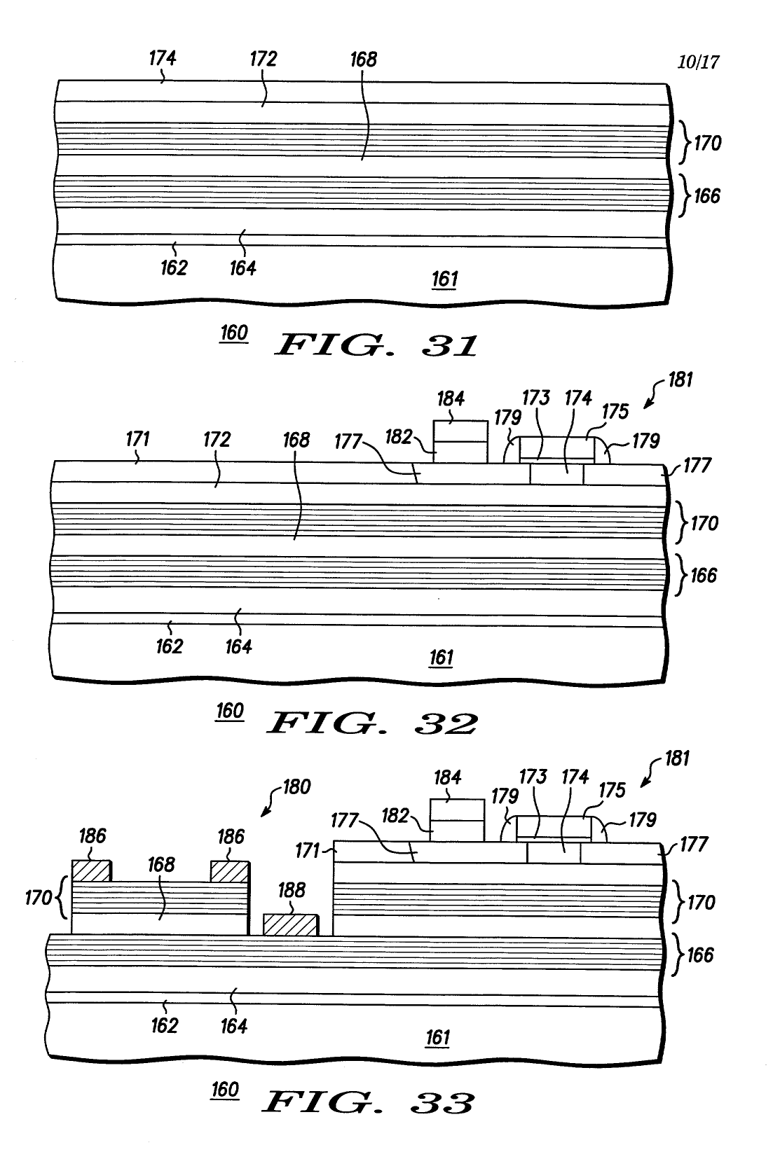

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5. A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The compound semiconductor layer can be formed by a number of processes and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit. A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 31-37 include illustrations of one embodiment.

FIG. 31 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 31, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 32, the MOS portion is processed to form electrical components within this upper monocrystalline Group IV semiconductor layer 174. As illustrated in FIG. 32, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P+ doped, and a lower portion 182 remains substantially intrinsic (undoped) as illustrated in FIG. 32. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 184 is formed, the insulating layer is then removed to form the resulting structure shown in FIG. 32.

The next set of steps is performed to define the optical laser 180 as illustrated in FIG. 33. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 33. Contact 186 has an annular shape to allow light (photons) to pass out of the upper mirror layer 170 into a subsequently formed optical waveguide.

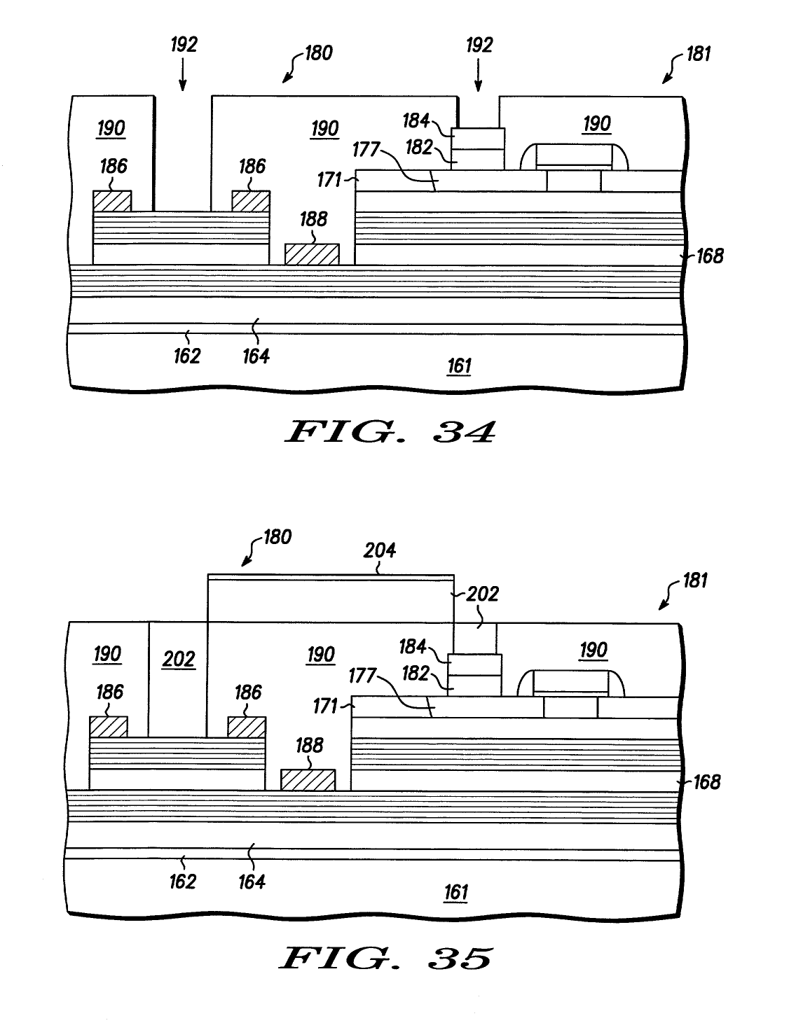

An insulating layer 190 is then formed and patterned to define optical openings extending to the contact layer 186 and one of the doped regions 177 as shown in FIG. 34. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 35. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 35.

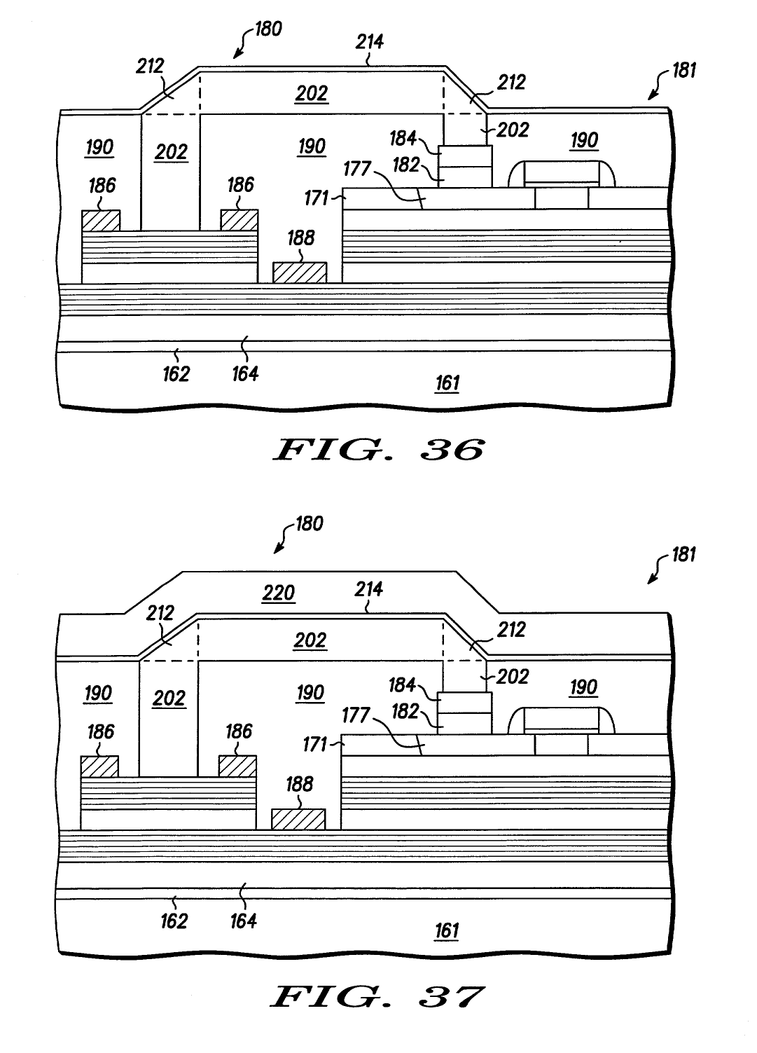

The balance of the formation of the optical waveguide, which is an optical interconnect, is completed as illustrated in FIG. 36. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 36 illustrate the border between the high refractive index materials 202 and 212. This designation is used to identify that both are made of the same material but are formed at different times.

Processing is continued to form a substantially completed integrated circuit as illustrated in FIG. 37. A passivation layer 220 is then formed over the optical laser 180 and MOSFET transistor 181. Although not shown, other electrical or optical connections are made to the components within the integrated circuit but are not illustrated in FIG. 37. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 161, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal.

### EXAMPLE 7

The etching protocols used on the workpieces, and as exemplified in more detail below with reference to FIGS. 38-47, are not necessarily limited to processing of a composite semiconductor structure starting material as exemplified in FIG. 1, but they also can be applied to variant composite structures thereof described herein, for example, with reference to FIGS. 2, 3, 12, 20, 23, 24, 25, 29, 30 and 37. Also, the specific materials described in connection with the discussion of FIGS. 38-47 are illustrative only.

Significant thickness variation often exists in semiconductor substrates such that even a uniform etch can have an undesirable outcome with some vias or trenches either under etched, over etched, or combinations of both in the silicon substrate. Lapping and chemical mechanical polishing (CMP) planarizing techniques and the like in the art can be used to reduce surface non-uniformities; however, sufficient semiconductor substrate thickness must be preserved to provide a robust wafer that can tolerate handling and use. The present invention provides an etch stop layer in a composite semiconductor structure to be used in conjunction with semiconductor wafer substrates, such as silicon wafers, whereby anisotropic etching of via openings completely through the thickness of the silicon substrate can be accomplished without causing an undue inadvertent etch attack in the thinner high quality monocrystalline layer being approached from its back side.

As discussed above, and referring to FIG. 38, the present invention uses buffer layer 24 already present in the integrated composite structure 20 not only for mitigating and eliminating lattice mismatch issues, but also in an additional role as an etch stop used during subsequent fabrication of active devices and/or interconnections between opposite major sides of the integrated structure 20, as shown in FIGS. 39-47. The present invention provides this etch stop function without adversely affecting the crystal quality and the lattice mismatch stress relief achieved in the composite semiconductor structure. The manner of forming semiconductor structure 20, including layers 22, 28, 24, 30 and 26, has already been described herein, and reference is made thereto. The single crystal silicon substrate 22 includes a front side 221 and a back side 223. The perovskite oxide film 24 has a side 241 facing the silicon substrate 22 and an opposite side 243 facing compound semiconductor layer 26. Monocrystalline compound semiconductor layer 26 has a side 263 facing the perovskite oxide film 24, and an opposite side 261. For purposes of the illustrations shown in FIGS. 38-47, the monocrystalline compound semiconductor layer 26 can be a Group III-V semiconductor material, such as those described supra.

Metal oxide thin film materials, such as SrTiO₃ (STO), have been used previously as a dielectric material for various electronic devices such as capacitors; however, the use of STO and other perovskite metal oxides as an etch stop for anisotropic etching in composite semiconductor structures is introduced in the present invention.

A) Wet Etch Process Routes For Making Vias to Etch Stop

As illustrated in FIG. 39, a selective wet etching procedure is implemented on a single crystal silicon substrate 22 that is (100) orientation.

The single crystal silicon substrate 22 can be patterned with a mask for wet etching by conventional known methods for that general purpose. For example, the surface can be oxidized and then patterned photolithographically to leave silicon dioxide or silicon nitride masking areas 29 on the silicon surface 221 to define exposed, unmasked regions on the substrate where vias or trenches are desired to be etched through the thickness of silicon substrate 22.

Preferably, masking layer 29 is a layer comprising silicon dioxide which is grown thermal oxide or deposited using low pressure chemical vapor deposition (LPCVD) on the exposed face of the silicon substrate. A photoresist (not shown) is then used to expose portions of the silicon dioxide masking layer on the top side of the single crystal silicon substrate. An additional layer of photoresist (not shown) or other suitable removable maskant is coated on the opposite side of the composite semiconductor structure 20 to completely and uniformly cover and protect the high quality monocrystalline semiconductor layer 26 located on the opposite (front) side of the composite structure during etching and processing of the silicon substrate side. A fixture may also be used to protect the front side of the wafer.

A wet etch solution, such as buffered hydrofluoric acid, or RIE etching (e.g., using CF₄/H₂), is then used to remove the exposed portions of the silicon dioxide masking layer overlying the silicon substrate to expose the underlying surface regions of the substrate surface. The wafer may alternatively be placed in a fixture that protects the front surface of the wafer from the wet etch solution.

As shown in FIG. 39, anisotropic crystallographic wet etching is performed on the exposed unmasked surface region of the silicon substrate 22 using the masking layer 29 as a mask resulting in removal of bulk material from the silicon substrate at a rate depending on crystallographic direction. That is, the progress of the wet etch is orientation dependent.

It will be understood that orientation-dependent etching of silicon of (100) orientation with a hydroxide-based wet etchant creates precise V-shaped grooves 211 and 231, the side edges being (111)-planes at an angle of 54.7 degrees from the (100) surface, and not straight or vertical-walled holes as obtained with (110) silicon. Consequently, care must be taken to ensure that each etch window created by patterned masking 29 used for wet etching (100) silicon is sufficiently large to permit the V-shaped groove to reach the etch stop layer 24 before the V-shaped groove is completed and the etch concludes. As illustrated in FIG. 39, this results in a via opening a V-shaped groove having a flat-bottom at the tip. It will be understood that one or any plurality of via openings could be formed in the silicon substrate 22 depending on the application envisioned.

The selective wet etchant used for this anisotropic crystallographic etch procedure, and the alternative described below relative to a (110) silicon substrate, preferably comprises an alkaline solution capable of generating hydroxide ions, such as tetramethylammonium hydroxide (TMAH), or the like. However, solutions comprising cesium hydroxide, ethylenediamine pyrocatechol (EDP), ethylenediamine/ pyrocatechol/water (EPW), ethylenediamine/pyrocatechol/quinoxaline/water (a modified EPW), potassium hydroxide, lithium hydroxide, sodium hydroxide, or other suitable hydroxide-ion generating chemicals that can be used to selectively etch crystal planes on single crystal silicon also could be used.

The single crystal silicon substrate 22 can also have a flat cut along a (111) or (110) crystal plane which is used to align single crystal silicon substrate 22 to semiconductor processing equipment.

The wet etch will proceed until it reaches amorphous oxide layer 28 such that the etch stops at the interface of the silicon substrate 22 and buffer/etch stop layer 24. The selective wet etchant used on the silicon substrate 22, such as those described below, will not appreciably etch the buffer/etch stop layer 24. The silicon oxide transition region 28 is not appreciably affected by the selective wet etchant used on the silicon substrate 22. The amorphous silicon oxide layer 28 present at the bottom of the vias 211, 231 after etching them in substrate 22 can be removed by brief exposure to a separate etchant, for example, such as by wet etching with buffered HEF (1000 Angstroms/min etch rate), or dry etching with CH₄/H₂ RIE (450 Angstroms/min etch rate). The hydroxide-based wet etchants described herein also do not appreciably attack the buffer/etch stop layer 24, at least not over a short period of time. However, extended exposure of the buffer/etch stop layer to the wet etchant used on the silicon is not desirable as some incidental isotropic etching may occur. Although the perovskite oxide film 24 will have the same crystal orientation as the silicon substrate 22 according to preferred embodiments of the invention, the wet etchant used on silicon substrate 22 not only etches selectively insofar as crystallography but also is material specific.

In an alternative embodiment illustrated in FIG. 40, the semiconductor structure starting material is structure 34 of FIG. 3 as described elsewhere herein, instead of structure 20 of FIG. 1. In this instance, the selective wet etch of the single crystal silicon substrate 22 stops at side 245 of amorphous oxide layer 36. In FIG. 40, as well as FIG. 45 discussed infra, layer 38 is illustrated in the examples as being comprised of the above-described template formed of at least one monolayer of a constituent of the monocrystalline compound semiconductor layer 26 which interacts with monolayered capping layer 30 to form a template for epitaxial growth of layer 26. Other materials described supra for layer 38 also could be used.

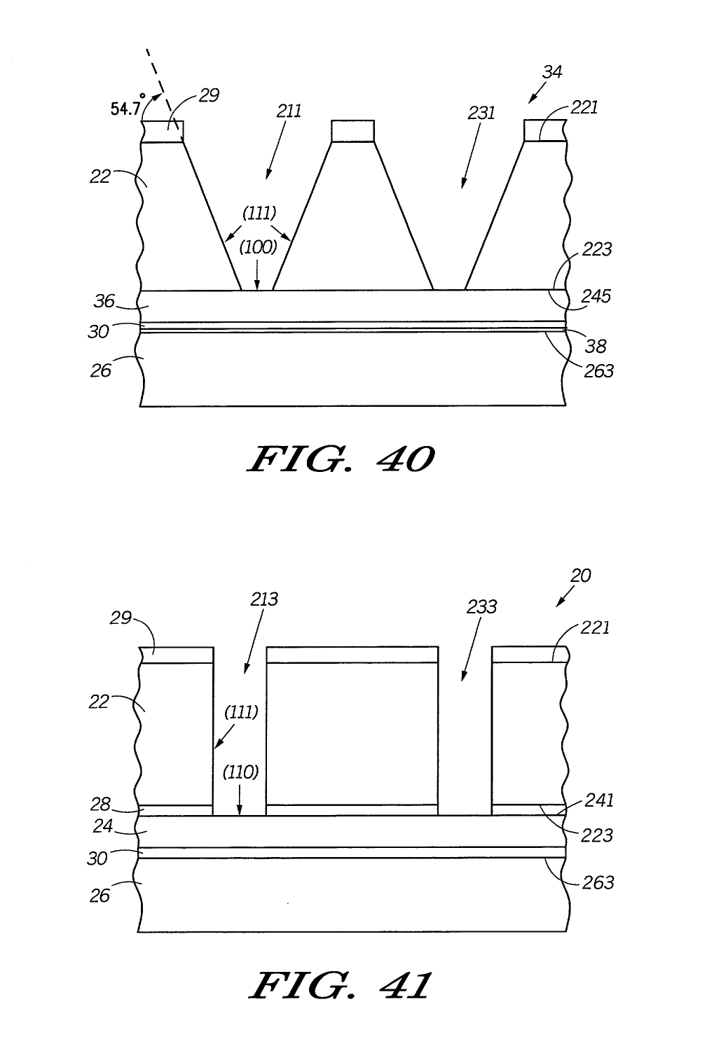

Referring now to another alternative illustrated in FIG. 41, the exposed major surface 221 of the single crystal silicon substrate 22 is in a (110) crystal plane for purposes of this illustrated embodiment. To form the vias or trenches 213 and 233 in the silicon substrate 22, a selective wet etch is used which only removes the exposed portions of single crystal substrate 22 that are in the (110) plane. As this selective wet etch proceeds, the wet etch will expose any planes having a (111) orientation which serves to define via openings.

The width of trench structure 213, 233 is defined by two parallel (111) planes. Since the silicon etch is anisotropic, the bottom of the trench structure is in the (110) crystal plane and is essentially parallel with the top surface 221 of single crystal silicon substrate 22.

The advantages of using selective wet etching for forming the vias or trenches in the silicon substrate, such as illustrated in FIGS. 39-41, is that the rate of wet etching is relatively faster than most anisotropic RIE etch techniques for etching single crystal silicon. In addition, selective wet etching permits formation of openings of very small size as there is no significant build-up of residue on the sidewalls and bottom of the hole as the etch operation proceeds. For instance, selective wet etching can permit sub-micron openings to be formed in the silicon substrate. Also, selective wet etching permits batch processing to increase throughput, as compared to single wafer RIE processing.

B) Dry Etch Processing Route to Etch Stop With End-Point Detection

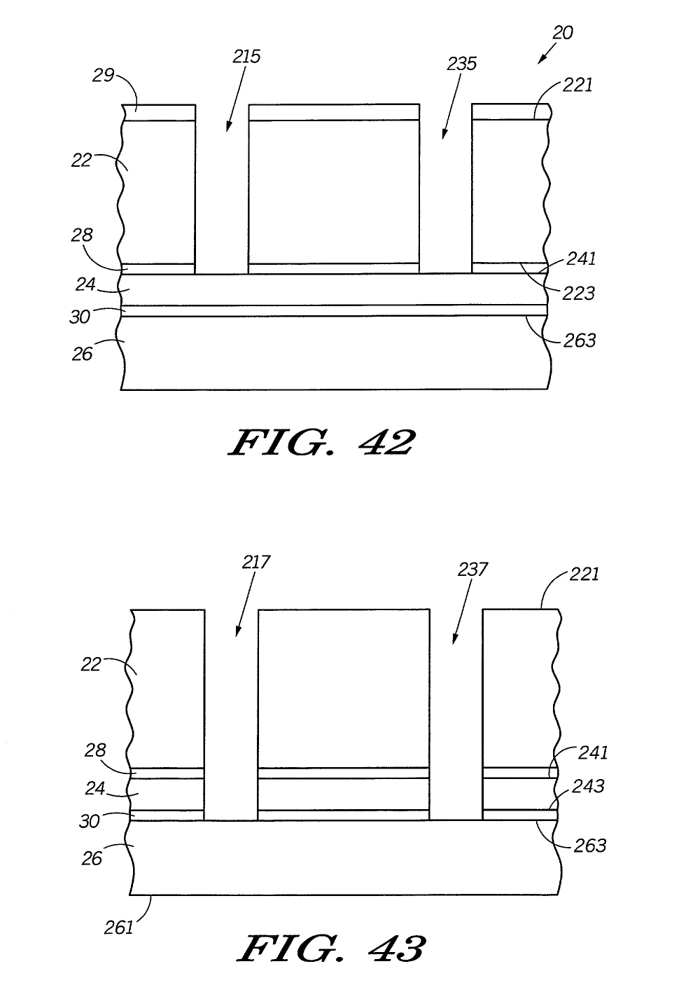

Referring now to FIG. 42, dry etch, e.g., plasma-assisted etching, also can be used to form vias or trenches 215 and 235 in single crystal silicon substrate 22. The use of RIE etching, for instance, may burrow more slowly through the silicon substrate 22 than selective wet etching, but offers the advantage of permitting real time detection of the etch end point when the etch reaches the buffer/etch stop layer 24, and also high aspect ratio vias can be formed.

As with the wet etching embodiment of FIG. 41, the use of dry etching also can be used to form vias with essentially vertical sidewalls being formed in the silicon substrate 22.

Reactive ion etching (RIE) processes, for example, can be used for dry etching the vias 215 and 235 in silicon substrate (22). RIE processes capable of providing anisotropic etching of the silicon substrate 22 with appropriate etch selectivity as between silicon and a masking layer 29 used to define openings on the surface 221 of the silicon substrate 22 are generally known in the art, including, for example, RIE using SF₆/Cl₂. Suitable masking layers for such RIE processes for silicon are also known, including silicon dioxide, and silicon dioxide used in combination with other dielectric layers such as silicon nitride, and so forth. Suitable techniques for patterning these masks also are well known. The mask is made thick enough to tolerate any erosion by sputtering (physical impact) effects concomitant with the chemical removal mechanism(s) of the RIE process used.

Endpoint detection means can be used in conjunction with this RIE processing because a number of standard dry etchants useful for anisotropic etching of silicon also attack many of the perovskite metal oxide buffer/etch stop layer materials preferred in this invention. For instance, standard reactive ion etching plasmas for silicon including halogenated gases, such as chlorinated, fluorinated, or brominated gases, may have insufficient selectivity between the silicon substrate 22 and the perovskite metal oxide material in layer 24. As noted earlier, perovskite film 24 (or amorphous oxide layer 36) may have a thickness as small as about 2 to about 100 nm. To make sure that the RIE used to form vias 215 and 235 through silicon substrate 22 do not advance through buffer film 24 and begin attacking the back side of high quality monocrystalline compound semiconductor film 26 in a non-controlled manner before that etch procedure is stopped, end point detection is useful to permit the RE used in making vias 215 and 235 to be terminated quickly upon reaching layer 24. In this way, the layer 24 provides a buffer zone that the via etching procedure through silicon substrate 22 can safely reach and terminate before any uncontrolled etch attack of monocrystalline film 26 can occur.

To stop the etch of the vias 215, 235 once they clear the thickness of the silicon substrate 22 and expose layer 24, silicon endpoint detection is performed in situ and in real time by a suitable spectroscopic analyzer techniques. Suitable endpoint detection between the semiconductor substrate 22 and etch stop layer 24 can be conducted using generally known or useful optical end-point detection systems known and available in the semiconductor fabrication arts, including optical interferometric techniques. End point detection using laser-reflected light techniques also could be employed, using methods and equipment known in the art for this purpose. Alternatively, a mass-spectrometric analysis of the etching plasma also could be employed to detect when a material in the metal oxide etch stop layer 24 is liberated from the surface of the etch stop layer 24 into the plasma. The interface of the substrate 22 and etch stop layer 24 is assumed to have been reached when the spectrometric analysis of the plasma indicates the presence of a material or reaction product typical of the etch stop layer 24, such as strontium in the case of an STO layer 24. At that point, the RIE process is discontinued.

One basic strategy that can be used for the end point detection involves exposing the semiconductor substrate 22 to a plasma discharge appropriate to anisotropically etch into exposed surface regions of the semiconductor substrate, and optically detecting an endpoint of the via forming step at the interface of the semiconductor substrate 22 and etch stop layer 24 by passing a portion of electromagnetic radiation, which corresponds to a frequency of radiation associated with a preselected excited species including material liberated from the semiconductor substrate 22 or etch stop layer 24 by the plasma discharge into a radiation detector. The radiation detector produces an output signal dependent upon the intensity of the portion of radiation. The RIE process is discontinued when the detected output signal reaches a predetermined threshold value.

For example, the portion of electromagnetic radiation being continuously monitored by the radiation detector during the RIE process can correspond to a frequency of radiation associated with a preselected excited species related to material liberated from the etch stop layer by the plasma discharge, such as a metal contained therein, and the predetermined threshold value would be reached by the detected output signal rising above the threshold value (such as when the etch reaches the substrate/etch stop layer interface). At that point, the RIE process is discontinued.

Alternatively, the portion of electromagnetic radiation being monitored corresponds to a frequency of radiation associated with a preselected excited species including material liberated from the semiconductor substrate by the plasma discharge, such as silicon, and the predetermined threshold value is reached by the detected output signal falling below the threshold value (such as when the etch reaches the substrate/etch stop layer interface). At that point, the RIE process is discontinued.

Because of the extreme thinness of oxide film 28 in FIG. 42 (viz., 5-50 Angstroms), it generally will be etched off by the RIE etchant used on silicon substrate 22 in most cases, or alternatively, a separate brief ₄RIE etchant can be used to remove it at the bottom of the via 215 or 235 after completing the etch through the thickness of the substrate 22.

Ion milling, such as with argon, is less preferred as a method of dry etching the silicon substrate 22 due to the increased debris generated, which increases the risk of contamination, increased crystal damage, and non-selectivity as between the substrate and etch stop layer, and so forth.

C) Hybrid Etching Process Route to Etch Stop

The selective wet etch process, as described above in connection with FIGS. 39-41, alternatively could be used to etch partly, but not completely, through the thickness of single crystal silicon substrate 22, and then the dry etch process with end point detection, as described above in connection with FIG. 42, could be used to advance the vias until they reach the buffer/etch stop layer 24. This approach would offer combined advantages of relatively rapid etching through the bulk of the substrate 22 via wet etching, with the precision of the real time end point detection possible with dry etching. It also would lessen the opportunity for debris to collect along the sidewalls and bottom of the via due to any sputtering effects associated with RIE processing.

D) Etching of Buffer/Etch Stop Layer

Referring now to FIG. 43, when it is desirable to advance the vias formed in any of the partially processed workpieces shown in FIGS. 39, 42 or 43 through the buffer etch stop layer 24 until reaching the back side 263 of monocrystalline material layer 26, the following procedures can be employed. For instance, this etch is needed when backside connections to monocrystalline material layer 26 are desired. These connections must be directly made, as the metal oxide materials described herein for etch stop layer 24 generally are dielectric and electrical insulators, except for strontium ruthenate.

Dry and wet etching techniques are available to perform this step. For instance, the perovskite oxide material in etch stop layer 24 material can be wet etched by photolytically enhanced, anisotropic etching. In this regard, the metal oxide film can be anisotropic wet etched by a technique of contacting exposed portions of metal oxide film with a liquid solution of hydrochloric and/or hydrofluoric acid, and then exposing the acid solution (e.g., 12M HCl) to electromagnetic radiation (e.g., collimated visible/ultraviolet radiation) produced by a radiation source (e.g., a 200 Watt mercury xenon arc lamp), which initiates an anisotropic, liquid phase photochemical etch of the perovskite metal oxide film. Unless the procedure is performed photolytically, the HCl acid can attack the metal oxide isotropically, which increases the risk of sidewall erosion. Sidewall erosion may be undesirable as it can decrease the aspect ratio of the via when it is advanced through the perovskite oxide layer to ultimately expose the back side location of the monocrystalline compound semiconductor layer.

Since the thickness of the perovskite oxide layer 24 will be known for a workpiece, and the etch rate for the wet etching system can be predetermined for the workpiece, the duration of the wet etch needed to reach the backside 263 of the monocrystalline material layer can be predicted as a function of time and thus timed, and at which point the etching of buffer/etch stop layer 24 can be terminated at the proper time.

As dry etching techniques for etch stop layer 24, the etchant used should have a high selectivity for the perovskite oxide material with respect to mask (not shown) formed over the silicon surface 221. This etch of layer 24 can be accomplished using RIE processing using one or more halogen or halogenated gases (e.g., fluorine, chlorine, CF₄) at elevated temperatures (generally greater than 400° C., and preferably 500-800° C.), in combination with use of a hard mask (not shown) on the silicon surface. For example, the hard mask could be formed of oxides of transition metals, BN, Cr₂O₃, AlN, and so forth. After completing the etch through layer 24, the hard mask can be removed by any standard etch process for that purpose. For example, an organic release layer can be provided under the hard mask at the surface of the silicon substrate to permit subsequent lift off removal of the hard mask. Noble gases, such as argon, can be included in the etch plasma to impart ion milling effects to increase the removal rate on the perovskite oxide, although the ion milling will not be selective to the perovskite oxide and the mask will need to have sufficient thickness to tolerate the sputtering effects. Also, the etch plasma can include oxygen or oxygen compounds to help prevent reduction of the metal oxide in layer 24 during the RIIE process.

Spectroscopic end point detection techniques, such as generally described above, also can be used to monitor when the backside 263 of the monocrystalline material layer 26 is reached during the RIE processing used to etch the layer 24, at which point the etch of etch stop layer 24 is terminated. For illustration sake, FIG. 43 shows this process step performed on layer 24 as conducted on a starting material based on the intermediate structure shown in FIG. 42. It will be appreciated that the above etch procedures described in connection with FIGS. 39-43 can be used to advance the via openings through buffer/etch stop layer 24, such as when it is comprised of a monocrystalline perovskite oxide material, such as described herein in connection with FIG. 1, or alternatively, they also can be used to advance the vias through buffer/etch stop layer 36 such as when it is comprised of an amorphous oxide material, such as described herein in connection with FIG. 3. Since capping layer 30 and template layer 38 (of structure 34) can be comprised of a total thickness of 1 to 10 monolayers, and include constituents of the capping layer 30 and the layer 26, for purposes of this illustration, no special etch procedures must be taken with respect to these two layers as they form a very thin interface between layers 36 and 26. Consequently, whether the etch of layer 36 is timed, or end point detection is used to detect when layer 26 is reached, the presence of capping/template interface 30/38 is not significant factor.

E) Backside Connections to Monocrystalline Material Layer

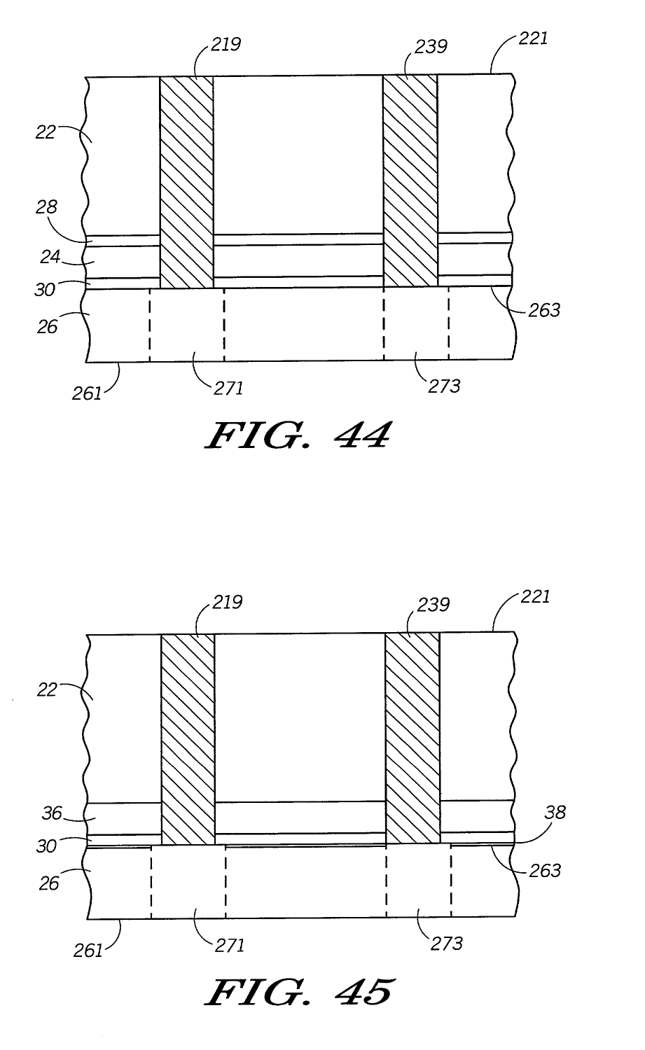

Referring now to FIG. 44, conductive via connections 219 and 239 are formed in the vias 217 and 237 (see FIG. 43). These connections 219 and 239 can be made to active regions or electronic circuitry 271 and 273 present in the monocrystalline compound semiconductor material layer 26. These conductive via connections can be formed by conventional methods known and used in the industry for that general purpose. For example, a via liner, such as Ti or TiN, and a metal such as tungsten, copper, or aluminum could be deposited in the vias 217 and 237 to form via connections to discrete locations at the backside 263 of monocrystalline material layer 26.

In an alternative embodiment illustrated in FIG. 45, the conductive via connections can be formed in a composite semiconductor structure according to FIG. 3 including an amorphous oxide layer 36. To accomplish this, the etching procedure used to advance the vias through the perovskite layer 24 to the back side 263 of the layer can be the same techniques described above in connection with FIG. 43. Then, the formation of the conductive via connections 219 and 239 can proceed as described above in connection with FIG. 44.

### EXAMPLE 8

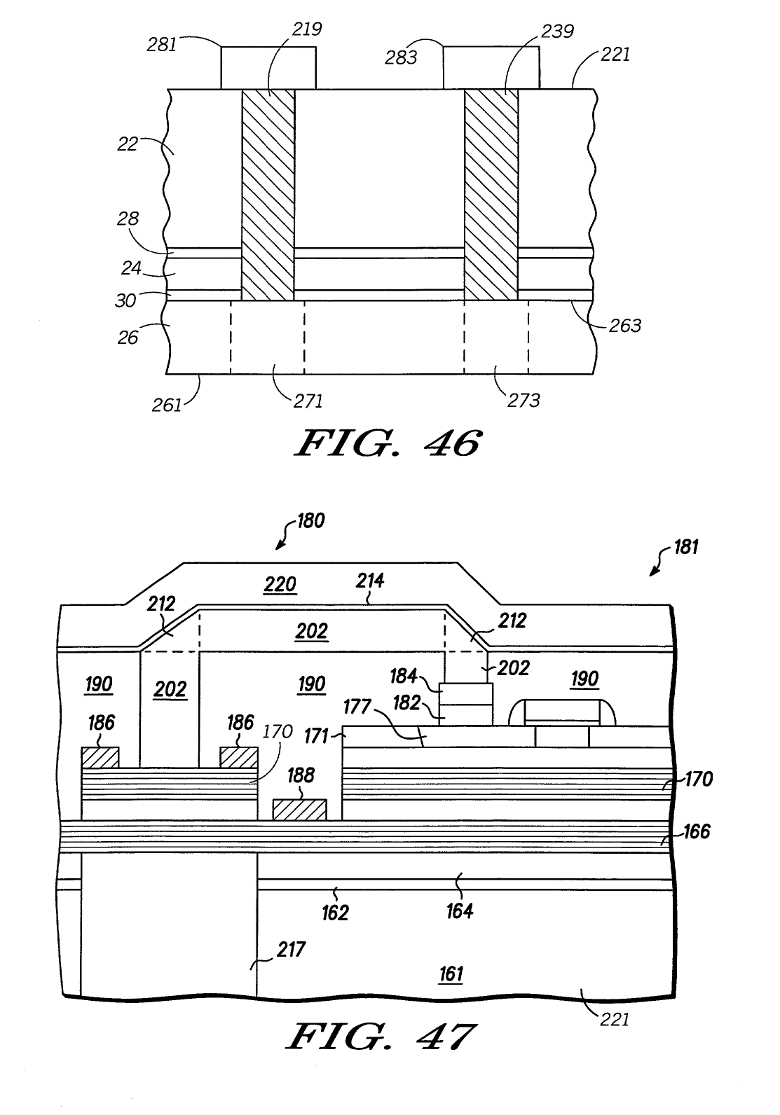

FIG. 46 illustrates schematically, in cross section, a process for forming a thermal via connection in a composite semiconductor structure in accordance with another embodiment of the invention using the structure of FIG. 38. This embodiment also could be practiced on other semiconductor structures described herein, including the structure 40 of FIG. 2 or the structure 34 of FIG. 3. The structure includes conductive via connections 219 and 239, as with FIG. 44, except that the conductivity of interest here is thermal and not electrical. The via connections 219 and 239 conduct heat from devices 271 and 263 in monocrystalline compound semiconductor layer 26 to heat dissipaters or heat sinks 281 and 283 disposed on the opposite exposed surface 221 of single crystal silicon substrate 22.

### EXAMPLE 9

Referring now to FIG. 47, a vertical cavity surface emitting laser structure 181 is provided according to another embodiment of the invention in a composite semiconductor structure according to FIG. 37 using the back side processing techniques such as described above in connection with FIGS. 42-43, and reference is made thereto. Monocrystalline silicon wafer 161 is equivalent to silicon substrate 22. Amorphous intermediate layer 162 and accommodating buffer layer 164, are comparable to layers 28 and 24, respectively, discussed above in connection with FIGS. 42-44. Layers 162 and 164 may be subject to an annealing process as described above in connection with FIG. 3 to form a single amorphous accommodating layer. In this specific embodiment, the layers needed to form the optical laser have been formed first, followed by the layers needed for the MOS transistor, as described above in connection with FIGS. 31-37, and reference is made thereto. The compound semiconductor layers 166 and 170 include alternating layers of monocrystalline compound semiconductor materials, as described above in connection with FIGS. 31-37. In one embodiment of the vertical cavity laser, a light emitting exit hole 217 is fabricated through silicon substrate 161, such as using the techniques described above in connection with FIGS. 42-44, permitting light generated by the optical laser 180 to be emitted from the bottom of the semiconductor structure 181. In another embodiment, a mirror stack for the laser can be formed from the silicon side 221 of the structure after forming and advancing the via 217 to the backside 263 of layer 26.

As can be appreciated, the present invention is well-suited for obtaining highly-aligned access to the back side of the monocrystalline material layer 26. This backside access is useful for providing electrical contact to certain microelectronic devices, optoelectronic devices, and/or electronic circuitry, and so forth present in monocrystalline material layer 26. The thin metal oxide etch stop layer is crucial to avoid alignment problems from occurring between the via started in a semiconductor substrate, such as a “handle” wafer, and the back side areas of active regions or contact areas therefor located in the monocrystalline material layer. In this manner, a composite, integrated structure of dissimilar semiconductors and other materials, for example, can be processed as a single, unified structure combining structural robustness and high quality films for high performance microelectronic/optoelectronic devices.

In yet another embodiment of the invention, the vias can be formed as trenches having a variety of applications in semiconductor devices including, but not limited to, electrical isolation structures, alignment marks, and microstructures, formed in or involving the semiconductor substrate of the composite semiconductor structure. In this way, active devices can be formed in both the semiconductor substrate and the high quality monocrystalline material film of the composite semiconductor structure.

For instance, the etch process techniques described herein also can be used to form isolation trenches for active devices or microstructures (e.g., microsensors), and the like, to be formed at least in part in the silicon substrate 22. In such embodiments, the silicon substrate 22 would be not used exclusively as a Ahandle@ wafer. For example, the vias could be formed as isolation trenches in silicon substrate 22 in the fabrication of vertical lasers, which could include a bottom mirror formation on the substrate 22. The present invention permits a vertical laser to be formed in a composite semiconductor structure. The composite semiconductor structure could be processed according to the present invention in which the semiconductor substrate comprises silicon (Si) or compound silicon germanium (SiGe) to provide a relatively low cost, robust platform providing mechanical strength to the structure, while optionally being available for hosting active devices itself, if and when desired, while the high quality monocrystalline semiconductor layer is used as the primary medium in and upon which active devices and/or circuitry are formed and it comprises a group III-V semiconductor, such as GaAs, GaInAs, GaAlAs, InP, CdS, ZnSe and so forth.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film, said monocrystalline compound semiconductor layer having a back side facing said monocrystalline perovskite oxide film;
pattern masking the silicon substrate to define at least one exposed surface location thereof;
forming a via in the silicon substrate through the exposed surface location which stops at the monocrystalline perovskite oxide film before exposing the monocrystalline compound semiconductor layer; and
advancing the via to the back side of the monocrystalline compound semiconductor layer.

2. The process according to claim 1, further comprising depositing a conductive material in the via that is in contact with the monocrystalline compound semiconductor layer.

3. The process according to claim 1, further comprising forming a heat sink on an exposed major face of the silicon substrate, and forming thermal communication between the monocrystalline compound semiconductor layer and the heat sink through the conductive material in the via.

4. The process according to claim 1, wherein the epitaxially forming of the monocrystalline compound semiconductor layer comprises depositing an epitaxial Group III-V compound semiconductor material.

5. The process according to claim 1, wherein the via forming comprises exposing the silicon substrate to an anisotropic etchant having an etch selectivity to the silicon substrate over the monocrystalline perovskite oxide layer of at least approximately 10:1.

6. The process according to claim 1, wherein the via forming comprises exposing the silicon substrate to a wet etchant providing anisotropic crystallographic orientation etching thereon.

7. The process according to claim 1, wherein the via forming comprises exposing the silicon substrate to a wet etchant providing anisotropic crystallographic orientation etching thereon, wherein said wet etchant comprises an alkaline hydroxide solution.

8. The process according to claim 1, wherein the via forming comprises reactive ion etching the silicon substrate.

9. The process according to claim 1, wherein the via forming comprises:
exposing the silicon substrate to a plasma discharge to etch the via through the silicon substrate,
optically detecting when via reaches the monocrystalline perovskite film, and
discontinuing said via forming when such is optically detected.

10. The process according to claim 9, wherein the via forming comprises:
reactive ion etching the silicon substrate, and
optically detecting an endpoint of the via forming between the silicon substrate and the perovskite oxide film by passing a portion of electromagnetic radiation, which corresponds to a frequency of radiation associated with a preselected excited species including material liberated from the silicon substrate or perovskite oxide film by the plasma discharge into a radiation detector producing an output signal dependent upon the intensity of the portion of radiation, and
discontinuing said via forming when the detected output signal reaches a predetermined threshold value.

11. The process according to claim 1, wherein the via forming comprises: exposing the silicon substrate to a plasma discharge to etch the silicon substrate, detecting an endpoint of the forming step between the semiconductor substrate and the perovskite oxide film by monitoring the plasma discharge using mass-spectrometric analysis until a preselected excited species including material of the perovskite oxide film is detected, and discontinuing said via forming upon said detection.

12. The process according to claim 1, wherein said via advancing comprises contacting the perovskite oxide film with an anisotropic wet etchant comprising a liquid solution at least one of hydrochloric acid and hydrofluoric acid, and then exposing the acid solution to electromagnetic radiation

13. The process according to claim 1, wherein said via advancing comprises exposing the perovskite oxide film to an anisotropic dry etchant comprising a plasma generated in a source gas including a halogen-containing gas.

14. The process according to claim 1, wherein said depositing of said monocrystalline perovskite oxide comprises selecting a perovskite oxide selected from the group consisting of strontium titanate, barium strontium titanate, barium titanate, strontium zirconate, barium zirconate, strontium hafnate, barium hafnate, and barium stannate.

15. The process according to claim 1, wherein the providing of the silicon substrate comprising selecting a silicon selected from the group consisting of (100) silicon, (110) silicon, and (111) silicon.

16. The process according to claim 1, wherein the providing of the monocrystalline silicon substrate comprises selecting a silicon having a thickness of about 12,000 to 25,000 nm, and the depositing of the perovskite oxide film comprising forming a perovskite oxide in a thickness of about 2 to about 100 nm, and the epitaxially forming of the monocrystalline compound semiconductor layer comprising forming the compound semiconductor layer in a thickness of about 500 to about 10,000 nm.

17. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
heating said monocrystalline perovskite oxide film effective to transform the perovskite oxide film into an amorphous perovskite film;
pattern masking the silicon substrate to define at least one exposed surface location thereof;
forming a via in the silicon substrate through the exposed surface location which stops at the monocrystalline perovskite oxide film before exposing the monocrystalline compound semiconductor layer; and
advancing the via to the back side of the monocrystalline compound semiconductor layer.

18. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
at least one via extending through the silicon substrate and perovskite oxide film to at least the backside of the monocrystalline compound semiconductor material layer.

19. The semiconductor structure according to claim 18, wherein the via contains a conductive material which contacts the monocrystalline compound semiconductor layer.

20. The semiconductor structure according to claim 18, wherein the via contains a conductive material which contacts the monocrystalline compound semiconductor layer, and further comprising a heat sink on an exposed major face of the silicon substrate in thermal communication with the monocrystalline compound semiconductor layer through the conductive material in the via.

21. The semiconductor structure according to claim 18, wherein the monocrystalline compound semiconductor material layer is a Group III-V semiconductor material.

22. The semiconductor structure according to claim 18, wherein the monocrystalline perovskite oxide comprises a perovskite oxide material selected from the group consisting of strontium titanate, barium strontium titanate, barium titanate, strontium zirconate, barium zirconate, strontium hafnate, barium hafnate, and barium stannate.

23. The semiconductor structure according to claim 18, wherein the silicon substrate is selected from the group consisting of (100) silicon, (110) silicon, and (111) silicon.

24. The semiconductor structure according to claim 18, wherein the monocrystalline silicon substrate has a thickness of about 12,000 to 25,000 nm, the perovskite oxide film has a thickness of about 2 to about 100 nm, and monocrystalline compound semiconductor layer has a thickness of about 500 to about 10,000 nm.

25. A light-emitting semiconductor device comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
said monocrystalline compound semiconductor material comprises a light generating source including at least one mirror stack comprised of alternating layers of Group III-V semiconductor material layers; and
at least one via extending through the silicon substrate and perovskite oxide film to the mirror stack at the backside of the monocrystalline compound semiconductor material layer.

26. The light-emitting semiconductor device according to claim 25, where said device comprises a vertical cavity surface emitting laser.

27. The light-emitting semiconductor device according to claim 25, where said device comprises a light emitting diode.
